(19) United States
(12) Patent Application Publication
(10) Pub. No.: US 2014/0009048 A1
(43) Pub. Date: Jan. 9, 2014

(54) CABINET FOR ELECTRONIC APPARATUS AND AN ELECTRONIC APPARATUS

(71) Applicant: NEC Personal Computers, Ltd, Tokyo (JP)

(72) Inventor: Tsunenori Yanagisawa, Tokyo (JP)

(21) Appl. No.: 13/928,982

(22) Filed: Jun. 27, 2013

(30) Foreign Application Priority Data
Jul. 4, 2012 (JP) 2012-150948

(51) Int. Cl. H05K 5/04

(52) U.S. Cl. CPC H05K 5/04
USPC 312/223.1

(57) ABSTRACT

In a cabinet for electronic apparatus, when Mg—Li alloy is employed to reduce weight of the cabinet and depressions are molded on a surface of the cabinet through presswork by using the Mg—Li alloy, neither a rough surface nor a crack appears in any bent portion forming the depressions of the cabinet. In a cabinet for electronic apparatus including a bump shape including at least one surface formed by conducting presswork for magnesium-lithium alloy, the bump shape is a shape in which a new surface formed when a reference surface before the presswork of the magnesium-lithium alloy is pushed toward the inside of the cabinet by the presswork and is placed apart from the reference surface is surrounded by the reference surface, the surface has a plate thickness t (mm) in a range of 0.4≦t≦2.0, and at least one bent portion constituting the bump shape has a radius of curvature R (mm) in a range of t≦R.

### BACKGROUND OF THE INVENTION

1. Field of the Invention

The present invention relates to a cabinet for electronic apparatus formed through presswork by use of a magnesium (Mg)-lithium (Li) alloy and an electronic apparatus including the same.

2. Description of the Prior Art

It has been required to reduce thickness and weight of electronic apparatuses such as a mobile notebook personal computer. Hence, this results in requirements to reduce thickness and weight of the cabinet for such electronic apparatuses. To secure a good design and rigidity of the cabinet, light metal having a low specific gravity such as magnesium having a specific gravity of 1.8 is employed as a material of the cabinet. For example, Japanese Patent Laid-Open Ser. No. 2011-456587 describes an invention regarding an exterior part of a cabinet formed in the shape of a container by use of presswork such as drawing for a magnesium alloy.

Further, Japanese Patent Laid-Open Ser. No. 2003-170227 describes a technique for a top cover or a cabinet for a hard disk drive unit. The top cover is molded by fully conducting reduction in area for a plate of Mg—Li alloy in the presswork. The top cover has the contour of a flange perpendicularly formed in an outer periphery of its side wall.

For recent electronic apparatuses such as a mobile notebook personal computer, due to requirements of downsizing and higher performance of products of such apparatuses in addition to requirements of reduction in thickness and weight of the cabinet, parts internally arranged therein are downsized and are mounted with a higher integration ratio (higher mounting efficiency).

Also, Mg—Li alloy less in the specific gravity than magnesium, for example. LA141 having a specific gravity of 1.34 has been recently put to the market. If it is possible to use the alloy for the cabinet of a portable electronic apparatus, the weight thereof will he further reduced.

However, when the Mg—Li alloy is employed to mold the cabinet for electronic apparatuses such as a mobile notebook personal computer through the presswork, there occurs a problem, which has not been reported in the presswork conducted by use of the magnesium alloy described in Japanese Patent Laid-Open Ser. No. 2011-156587,

In the surface of the cabinet for electronic apparatus such as a notebook personal computer, there are formed, for example, screw holes to install the cabinet in the body of the computer and depressions to accommodate rubber pads to prevent slippage of the computer body. When molding the screw holes and depressions by presswork, it is required to take the good design on the surface of the cabinet into consideration.

For the screw holes, from the viewpoint of good design, it is necessary to secure the height and the diameter of the head of the screw such that the screw does not project over the surface when the computer is installed by use of the screw. Further, it is required to dispose a depression in the shape of a bump having an inclined portion which fits the inclination of the inside of the screw head. The bump-shaped depression includes two bent portions, that is, a bent portion on a boundary between the surface (flange) of the cabinet and the bump-shaped inclined portion and a bent portion on a boundary between the inclined portion and an upper surface portion of the depression. In this situation, for the good design, the radius of curvature is desirably reduced in each bent portion to the maximum extent.

However, when the screw hole and a depression are formed in a direction from the surface of the cabinet to the inside thereof through presswork by use of Mg—Li alloy, the plate of alloy originally having a flat shape is extended by using the two bent portions as boundaries, if the radius of curvature is too small in each bent portion, a problem appears in the bent portion in association with reduction in thickness of the plate, depth (height) of the depression, and the inclination of the inclined portion. That is, the bent portion is extended to cause a rough surface and/or a crack.

### SUMMARY OF THE INVENTION

It is therefore an object of the present invention to provide a cabinet for electronic apparatus which is devised in consideration of the problem and in which when the presswork is conducted for the metallic plate including Mg—Li alloy adopted to further reduce the thickness to form depressions in bent portions of a surface of the cabinet, neither the rough surface nor the crack appears in the bent portions for the depressions of the cabinet.

In accordance with the present invention made through research and development by the inventors to meet the requirements described above, there is provided a cabinet for electronic apparatus including a bump shape including at least one surface formed by conducting presswork for magnesium-lithium alloy, wherein the bump shape is a shape in which a new surface formed when a reference surface before the presswork of the magnesium-lithium alloy is pushed toward the inside of the cabinet by the presswork and is placed apart from the reference surface is surrounded by the reference surface, the surface has a plate thickness t (mm) in a range of 0.4≦t≦2.0, and at least one bent portion constituting the bump shape has a radius of curvature R (ram) in a range of t≦R.

In accordance with the present invention, the cabinet is much more reduced in weight and it is possible to prevent the rough surface and the crack in the bent portions for the depressions formed on the surface of the cabinet.

### BRIEF DESCRIPTION OF THE DRAWINGS

The objects and features of the present invention will become more apparent from the consideration of the following detailed description taken in conjunction with the accompanying drawings in which;

FIG. 1 is a simplified perspective view showing a bottom case 10 employed as a Mg—Li cabinet for a portable computer 1 in an embodiment of the present invention;

FIG. 2 is a magnified view showing a depression 11 of a screw hole viewed from a bottom surface of the embodiment;

FIG. 3 is a cross-sectional view showing the depression 11 of the embodiment;

FIG. 4A is an image of a phenomenon of a rough surface appearing in a bent portion. when the radius of curvature of the bent portion is outside the allowable range in the bottom case;

FIG. 48 is an image of a bent portion without any rough surface in a bent portion having an appropriate radius of curvature in the bottom case;

FIG. 5A is a schematic diagram showing installability of an electronic part or the like when the radius of curvature is small in the bent portion of the bottom case; and

FIG. 5B is a schematic diagram showing installability of an electronic part or the like when the radius of curvature is large in the bent portion of the bottom case.

### DESCRIPTION OF THE EMBODIMENTS

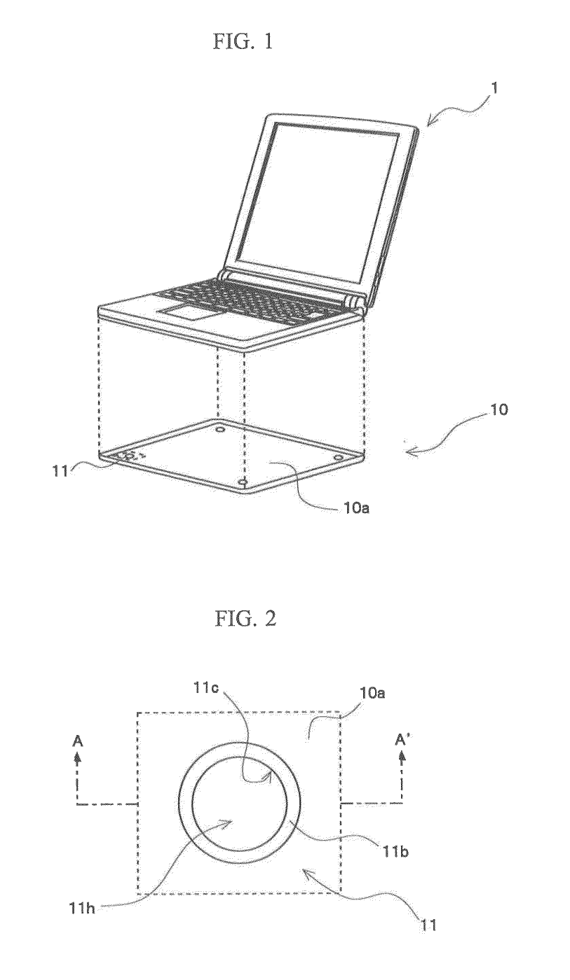

Referring now to the drawings, description will be given of a cabinet of Mg—Li alloy of the embodiment of the present invention. For example, as FIG. 1 shows, the bottom case 10 of the embodiment is employed on the bottom side of the portable, notebook electronic terminal 1. The bottom case 10 includes a plate of Mg—Li alloy having a low specific gravity. The combination of materials including magnesium and lithium of the alloy is not limited. That is, any type of Mg—Li alloy defined as, e.g., 1Z91 or LA.141, is available. From a viewpoint of reduction in weight and enhancement in rigidity of the cabinet, it is favorable to utilize LA141 having quite a low specific gravity.

The Mg—Li alloy for the bottom case 10 is prepared as below, Molten material including lithium, aluminum, and magnesium with predetermined percent by mass is cooled into an ingot of alloy. For the alloy ingot, a plastic process of a known method there is conducted. For example, rolling, forging, extruding, and drawing are carried out for the alloy ingot. Thereafter, an annealing process is conducted to re-crystallize the alloy deformed as a result of the plastic process. Finally, a surface treatment process is performed. for the alloy to remove therefrom a surface oxide layer and a lithium segregation layer.

To obtain the bottom case 10, presswork such as drawing is conducted for the Mg—Li alloy, to form the alloy into the contour of a rectangular box. In the present embodiment, to reduce the cabinet in thickness, the plate thickness t (mm) of the bottom case 10 is set to 0.4≦t≦2.0.

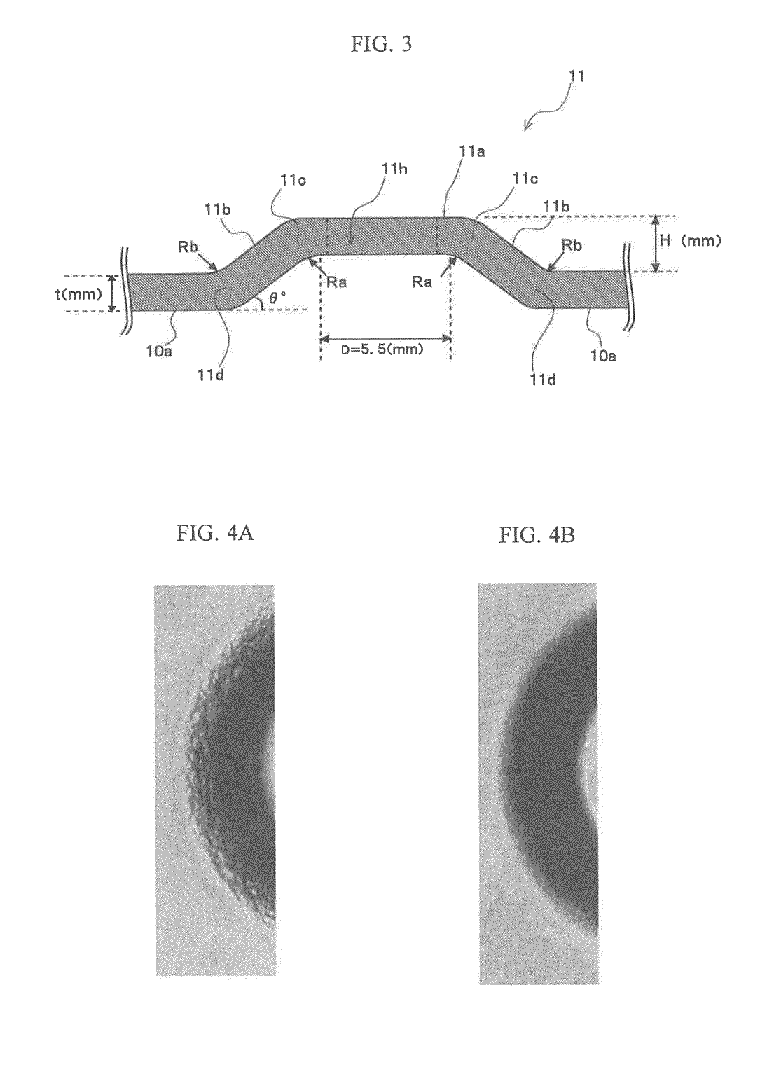

Referring to FIGS. 1 to 3, description will be given of the bump shape in the bottom case 10. FIG. 2 is a magnified view of a bump shape of the bottom case 10 shown in FIG. 1, the bump being viewed from the bottom surface. FIG. 3 is a cross-sectional view of the bump shape shown in FIG. 2, taken along line A-A′ perpendicularly passing the center of the bump shape. Assume in the present embodiment, that the surface of the Mg—Li alloy plate before presswork is the reference surface. In this situation, the bump shape is a shape in which a new surface formed when a reference surface before the presswork of the magnesium-lithium alloy is pushed toward the inside of the cabinet by the presswork and is placed apart from the reference surface is surrounded by the reference surface.

In the present embodiment, the bump shape indicates, for example, a depressed portion 11 including a screw hole 11h to attach the bottom ease 10 onto the portable electric terminal 1 as shown in FIG. 1 and any other depression formed in the bottom case 10. The other depression includes a depression formed in the bottom surface, e.g., a depression in which lubber pad is placed to prevent slippage of the body of the terminal 1. According to the definition of the bump shape, the depression is not limited to the depression shape including corners, but may be a round dome-like shape not having such corners.

As can be seen From FIGS. 2 and 3, the depression 11 includes new surfaces, i.e., depression upper surface 11a and a depression shoulder 11b. The depression upper surface 11a is a plane of the depression 11 to be pushed toward the depression side (inside of the cabinet). The depression shoulder 11b is a step inclined with a predetermined angle between the depression upper surface 11a and a bottom surface (flange) 10a as the reference surface.

The depression 11 of the present embodiment includes bent portions to form a depression, namely, a bent portion (second bent portion) lie and a bent portion (first bent portion) 11d. The bent portion lie is a bent portion formed between the depression upper surface 11a and the depression shoulder 11b. The bent portion lid is a bent portion formed between the depression shoulder 11b and the bottom surface 10a.

In the present embodiment, the bottom case 10 is formed such that the plate thickness t, the radius of curvature R of each of the bent portions 11c and 11d, and the height H of the depression 11 satisfy relationships of expressions below.

t≦R (1)

0H≦R+4 (2)

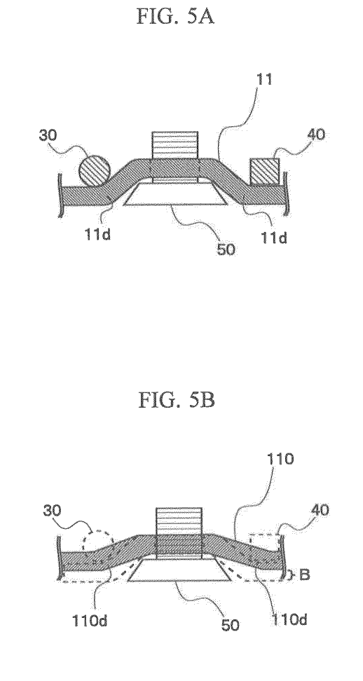

According to the present embodiment, when the radius of curvature R of the bent portions 11c and 11d are set to the lower-most value t of expression (1) or less, the material is non-uniformly extended in the bent portions 11c and 11d during the molding process of the cabinet. This leads to the phenomenon of rough surface in which the surface is not smooth, and the thickness of the bent portions are locally reduced and a crack takes place therein. Hence, it is not possible to obtain a cabinet for electronic apparatus applicable to practical uses. FIG. 4A shows an image of a cabinet surface with a rough surface portion. FIG. 4B shows an image of a cabinet surface not including such rough surface portion.

To prevent the rough surface and the crack during the molding of the cabinet, it is desirable in the design that the height H (difference in height between the depression upper surface 11a and the bottom surface 10a) of the depression 11 is within the range of expression (2).

Further, it is desirable that the inclination angle θ (°) between the bottom surface 10a and the depression shoulder 11b is set as 0<θ≦60. If the inclination angle θ of the depression shoulder 11b exceeds the upper limit, i.e., 60°, the material is excessively extended to cause the rough surface or the crack. Hence, it is not possible to obtain a cabinet for electronic apparatus applicable to practical uses. In such situation, the inclination of the taper of the inside of the screw does not match the depression shoulder 11b and interference takes place therebetween. As a result, the screw head projects from the bottom surface 10a.

As in the present embodiment, even when the plate thickness of the bottom case 10 is reduced to minimize the cabinet in thickness, it is possible to prevent the rough surface and the crack in the depression 11 of the bottom case. The bump shape is not limited to that of the present embodiment only if it satisfies the conditions described above. For example, a bump having a circular shape and a rectangular bump including a corner R may be employed. However, for a bump shape such as the dome shape not including any corner, there is formed one curved surface. That is, a plurality of surfaces are not formed as in the present embodiment. In this situation, the inclination angle θ of the curved surface is an angle between the reference surface and a tangent line drawn at a particular point on the curved surface.

In the present embodiment, the diameter D is set to 5.5 mm to cope with the M2.5 screw. However, the diameter D is not restricted by the embodiment, but may be set to any value only if it satisfies the conditional expressions described above.

To prevent the rough surface and the crack, the radius of curvature R. is not restricted by the upper-most value. The value of R is desirably set to 20.0 mm or less to filly secure the volume in the periphery of the shape to accommodate various boards in the cabinet, a liquid-crystal panel, and components such as battery to achieve functions of the electronic apparatus, as well as various electronic parts, codes, and the like. If the radius of curvature R exceeds 20.0 mm, the bump shape is too smooth, Hence, it is not possible to secure the volume to accommodate various electric and electronic parts.

For example, when the radius of curvature R is 20.0 mm or less as shown in FIG. 5A, it is possible to accommodate an electronic part 30 and a cable 40 on the inside of the depression 11. However, as FIG. 5B shows, when the radius of curvature R is more than 20.0 mm in the bottom case 11, the radius of curvature is small in the depression 110 and the inner wall of the depression 11 of FIG. 5A moves toward the inside of the cabinet. This results in reduction in the space to accommodate the electronic part 30 and the cable 40. Hence, it is not possible to mount these items 30 and 40 at predetermined positions.

Further, as FIG. 5B shows, when the radius of curvature R becomes larger in the two bent portions, the depression is relatively reduced in depth. Hence, the screw head projects from the bottom surface by a length of B. This deteriorates the good design of the cabinet. Also in this respect, it is desirable to set the upper limit of the radius of curvature R to 20.0 mm.

### EMBODIMENTS

Description will be given of embodiments of the present invention. In each embodiment, “San Maria” of Santoku is employed as the Mg—Li alloy. As conditions to mold the cabinet, the metallic mold temperature is adjusted in a range from the room temperature to 300° C. and a servo press or the like is employed.

For results of the molding, verification is conducted on each press sample molded as a cabinet for a personal computer having a vertical length of about 20.0 mm and a longitudinal length of about 300 mm. The cabinet is molded at a metallic mold temperature ranging from 100° C. to 300° C. At any mold temperature, each of the obtained cabinets satisfies the conditions described above.

### [Verification of Rough Surface and Crack]

In each embodiment, presence or absence of the rough surface is confirmed by viewing an image of a bent portion after the presswork, the image being magnified by a microscope. Also, presence or absence of the crack is visually confirmed in a similar fashion. Results of the continuation are presented as “good” when neither the rough surface nor the crack takes place, “rough surface” or “crack” when either one of the rough surface and the crack is present, and “rough surface and crack” when both thereof take place.

First, in a situation wherein the plate thickness of the cabinet is 0.4 min and the inclination angle of the depression shoulder is 60° in each bent portion of the depression (bump shape), verification is conducted for the rough surface and the crack by using embodiments and comparison examples in which “radius of curvature r of the bent portion” and “height H of the bump shape” are changed. Results of the verification are listed in Table 1 as below

TABLE 1

| | | r | H | Press performance judge result |
|---|---|---|---|---|
| Embodiment | 1 | 0.4 | 4.4 | Good |
| | 2 | 0.5 | 4.4 | Good |
| | 3 | 1.0 | 4.4 | Good |
| | 4 | 10.0 | 14.0 | Good |
| | 5 | 20.0 | 24.0 | Good |
| Comparison | 1 | 0.2 | 4.4 | Rough surface and crack |
| example | 2 | 0.3 | 4.4 | Rough surface |
| | 3 | 0.4 | 5.0 | Rough surface and crack |
| | 4 | 20.0 | 26.0 | Rough surface and crack |

In embodiment 1, r is 0.4 mm and H is 4.4 mm. In embodiment 2, r is 0.5 mm and H is 4.4 mm. In embodiment 3, r is, 1.0 min and H is 4.4 mm. In embodiment 4, r is 10.0 mm and H is 14.0 mm. In embodiment 5, r is 20.0 mm and H is 24.0 mm. According to verification, the press performance judge result is “good” for each of embodiments 1 to 5.

In comparison example 1 in which r is 0.2 mm and is 4.4 mm, there appears “rough surface and crack”. In comparison example 2 in which r is 0.3 mm and H is 4.4 mm, “rough surface” takes place. In comparison example 3 in which r is 0.4 mm and H is 5.0 mm, there appears “rough surface and crack”. In comparison example 4 in which r is 20.0 mm and H is 26.0 mm, “rough surface and crack” takes place.

Next, in a situation wherein the plate thickness of the cabinet is 2.0 mm and the inclination angle of the depression shoulder is 60° in each bent portion of the depression (bump shape), verification is conducted for the rough surface and the crack by using embodiments and comparison examples in which “radius of curvature r of the bent portion” and “height H of the bump shape” are changed. Results of the verification are listed in Table 2 as below.

TABLE 2

| | | r | H | Press performance judge result |
|---|---|---|---|---|
| Embodiment | 6 | 2.0 | 6.0 | Good |
| | 7 | 2.5 | 4.4 | Good |
| | 8 | 3.0 | 4.4 | Good |
| | 9 | 10.0 | 14.0 | Good |
| | 10 | 20.0 | 24.0 | Good |
| Comparison | 5 | 1.0 | 6.0 | Rough surface and crack |
| example | 6 | 1.5 | 6.0 | Rough surface |
| | 7 | 2.0 | 8.0 | Rough surface and crack |
| | 8 | 20.0 | 26.0 | Rough surface and crack |

In embodiment 6, r is 2.0 mm and H is 6.0 mm. In embodiment 7, r is 2.5 mm and H is 4.4 mm. In embodiment 8, r is 3.0 mm and H is 4.4 mm. In embodiment 9, r is 10.0 mm and H is 14.0 mm. In embodiment 10, r is 20.0 mm and H is 24.0 mm. According to verification, the press performance judge result is “good” for each of embodiments 6 to 10.

In comparison example 5 in which r is 1.0 min and H is 6.0 mm, there appears “rough surface and crack”. In comparison example 6 in which r is 1.5 mm and H is 6.0 min, “rough surface” takes place. In comparison example 7 in which r is 2.0 mm and H is 8.0 mm, there appears “rough surface and crack”. In comparison example 8 in which r is 20.0 mm and H is 26.0 mm, “rough surface and crack” takes place.

As can be seen from the verification results, when expressions (1) and (2) of the embodiments of the present invention and the conditions for the height of the hump shape and the inclination angle of the depression shoulder are satisfied, it is possible to obtain a cabinet for electronic apparatus in which neither the rough surface nor the crack takes place in any bent portion of the cabinet.

The present invention is applicable to cabinets for electronic apparatuses such as a notebook personal computer, a mobile terminal, and a slate terminal as well as to cabinets for white home appliances, cars, machines for industrial uses, toys, and the like.

It will be understood by those of ordinary skill in the art that various changes in form and details may be made therein without departing from the spirit and scope of the present invention as defined claims.

What is claimed is:

1. A cabinet for electronic apparatus comprising a bump shape comprising at least one surface formed by conducting presswork for magnesium-lithium alloy, wherein:
the bump shape is a shape in which a new surface formed when a reference surface before the presswork of the magnesium-lithium alloy is pushed toward the inside of the cabinet by the presswork and is placed apart from the reference surface is surrounded by the reference surface;
the surface has a plate thickness t (mm) in a range of 0.4≦t≦2.0; and
at least one bent portion constituting the bump shape has a radius of curvature R (mm) in a range of t≦R.

2. A cabinet for electronic apparatus in accordance with claim 1, wherein the at least one bent portion is a first bent portion formed at least in a boundary between the reference surface and the new surface.

3. A cabinet for electronic apparatus in accordance with claim 1, wherein the reference surface and a tangent line drawn at a particular point on the new surface form therebetween an angle θ(°) in a range of 0<θ≦60.

4. A cabinet for electronic apparatus in accordance with claim 2, wherein the reference surface and a tangent line drawn at a particular point on the new surface form therebetween an angle θ(°) in a range of 0<θ≦60.

5. A cabinet for electronic apparatus in accordance with claim 1, wherein the bump shape comprises:
a depression upper surface pushed toward the inside of the cabinet by the presswork; and
a depression shoulder comprising a first edge portion connected to an edge portion of the depression upper surface and a second edge portion connected to an edge portion of the reference surface, to thereby form a step between the depression upper surface and the reference surface.

6. A cabinet for electronic apparatus in accordance with claim 2, wherein the bump shape comprises;
a depression upper surface pushed toward the inside of the cabinet by the presswork; and
a depression shoulder comprising a first edge portion connected to an edge portion of the depression upper surface and a second edge portion connected to an edge portion of the reference surface, to thereby form a step between the depression upper surface and the reference surface.

7. A cabinet for electronic apparatus in accordance with claim 3, wherein the bump shape comprises:
a depression upper surface pushed toward the inside of the cabinet by the presswork; and
a depression shoulder comprising a first edge portion connected to an edge portion of the depression upper surface and a second edge portion connected to an edge portion of the reference surface, to thereby form a step between the depression upper surface and the reference surface.

8. A cabinet for electronic apparatus in accordance with claim 4, wherein the bump shape comprises:
a depression upper surface pushed toward the inside of the cabinet by the presswork; and
a depression shoulder comprising a first edge portion connected to an edge portion of the depression upper surface and a second edge portion connected to an edge portion of the reference surface, to thereby form a step between the depression upper surface and the reference surface.

9. A cabinet for electronic apparatus in accordance with claim 5, wherein the at least one bent portion is a second bent portion formed at least in a boundary between the depression. upper surface and the depression shoulder.

10. A cabinet for electronic apparatus in accordance with claim 6, wherein the at least one bent portion is a second bent portion formed at least in a boundary between the depression upper surface and the depression shoulder.

11. A cabinet for electronic apparatus in accordance with claim 7, wherein the at least one bent portion is a second bent portion formed at least in a boundary between the depression upper surface and the depression shoulder.

12. A cabinet for electronic apparatus in accordance with claim 8, wherein the at least one bent portion is a second bent portion formed at least in a boundary between the depression upper surface and the depression shoulder.

13. A cabinet for electronic apparatus in accordance with claim 5, wherein the depression upper surface and the reference surface have a difference in height H (mm) therebetween in a range of 0<H≦R+4.

14. A cabinet for electronic apparatus in accordance with claim 9, wherein the depression upper surface and the reference surface have a difference in height H (mm) therebetween in a range of 0<H≦R+4.

15. An electronic apparatus comprising a cabinet for electronic apparatus in accordance with claim 1.
